(19) United States
(12) Patent Application Publication
(10) Pub. No.: US 2024/0047396 A1
(43) Pub. Date: Feb. 8, 2024

(54) BONDED SEMICONDUCTOR DEVICE

(71) Applicant: Micron Technology, Inc., Boise, ID (US)

(72) Inventor: Thiagarajan Raman, Boise, ID (US)

(21) Appl. No.: 17/882,416

(22) Filed: Aug. 5, 2022

(51) Int. Cl. H01L 23/00; H01L 25/065

(52) U.S. Cl. CPC H01L 24/08; H01L 25/0657; H01L 24/16; H01L 24/73; H01L 24/32; H01L 24/05; H01L 24/81; H01L 24/13; H01L 2225/06513; H01L 2225/06517; H01L 2225/06524; H01L 2225/06541; H01L 2225/06527; H01L 2225/06589; H01L 2224/81203; H01L 2224/8183; H01L 2224/81895; H01L 2224/80896; H01L 2224/05687; H01L 2224/13147; H01L 2224/32145; H01L 2224/73204; H01L 2224/16145; H01L 2224/08145; H01L 2924/3511; H01L 2924/182; H01L 2224/16225; H01L 2924/1436; H01L 2924/1438; H01L 2924/1431

(57) ABSTRACT

This document discloses techniques, apparatuses, and systems for a bonded semiconductor device. A semiconductor assembly is described that includes a first semiconductor die having a first surface and a second semiconductor die having a second surface. A first electrical contact coupled to the first semiconductor die protrudes from the first surface and couples, through a solder joint, to a second electrical contact that couples to the second semiconductor die and protrudes from the second surface. A first non-conductive bonding structure protrudes from the first surface and couples to a second non-conductive bonding structure that protrudes from the second surface.

### TECHNICAL FIELD

The present disclosure generally relates to semiconductor device assemblies, and more particularly relates to bonded semiconductor devices.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 illustrates a simplified schematic cross-sectional view of an example semiconductor device assembly.

FIG. 2 illustrates a simplified schematic cross-sectional view of a semiconductor device assembly in accordance with an embodiment of the present technology.

FIG. 3 illustrates a simplified schematic cross-sectional view of a semiconductor device assembly in accordance with an embodiment of the present technology.

FIG. 4 illustrates a simplified schematic partial plan view of a semiconductor device assembly in accordance with an embodiment of the present technology.

FIGS. 5-7 illustrate simplified schematic cross-sectional views of a series of fabrication steps of semiconductor device assemblies in accordance with an embodiment of the present technology.

FIG. 8 illustrates a simplified schematic cross-sectional view of a semiconductor device assembly in accordance with an embodiment of the present technology.

FIG. 9 illustrates a simplified schematic plan view of a wafer that may be implemented to fabricate a semiconductor device assembly in accordance with an embodiment of the present technology.

FIG. 10 illustrates a schematic view showing a system that includes a semiconductor device assembly configured in accordance with an embodiment of the present technology.

FIG. 11 illustrates an example method for fabricating a semiconductor device assembly in accordance with an embodiment of the present technology.

### DETAILED DESCRIPTION

Electronic devices have been integrated with everyday life to enable users to tackle difficult problems and accomplish tasks more efficiently. Given the role these devices play in everyday life, users may desire their devices to be compact, creating significant spatial constraints for designers. Additionally, the discovery of new applications for electronic devices often requires increasingly capable devices that may store an increased amount of data or perform operations more efficiently. As such, designers are challenged to create improved devices without increasing the space in which the device is implemented.

Packaged semiconductor devices are often implemented within electronic devices to provide functionality (e.g., storage, processing, and so on) to the device. To enable an increase in device capability, semiconductor devices may be designed with greater density (e.g., storage density, memory density, logic density) to meet performance and spatial constraints. One such solution to increase the density of a semiconductor device is to vertically stack multiple semiconductor dies within a single package to increase the number of dies within a semiconductor device without increasing the footprint (e.g., horizontal area) of the device.

Stacked semiconductor devices (e.g., three-dimensional interface (3D1) packaging solutions) are often implemented as a set of multiple semiconductor dies formed from silicon wafers. The semiconductor wafers may be thinned (e.g., to less than 100 micrometers (μm)) to reduce the vertical thickness of the stacked semiconductor devices and satisfy the spatial constraints of the electronic device in which they are implemented, for example, based on the thickness of the electronic device. These dies are then physically and electronically connected to one another to secure and communicatively couple the stacked dies. Many solutions for connecting the dies, however, may be spatially inefficient or inhibit the operations of the multiple dies.

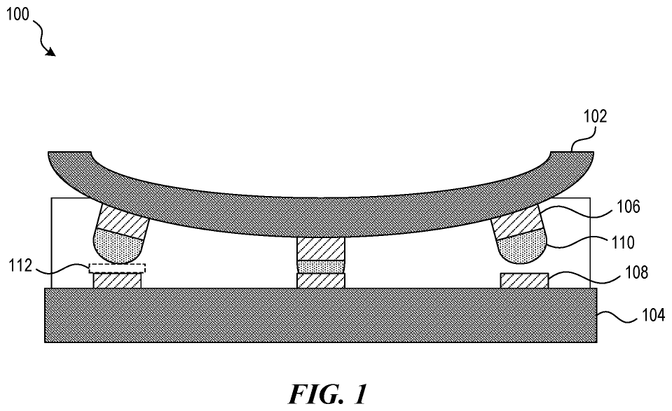

Take FIG. 1, for instance, which illustrates a semiconductor assembly that includes a semiconductor die 102 connected to a semiconductor die 104 (e.g., or substrate). The semiconductor die 102 includes electrical contacts 106 (e.g., interconnects) that couple to electrical contacts 108 of the semiconductor die 102 through solder joints 110 (e.g., solder balls, solder bumps, etc.). The semiconductor die 102 or the semiconductor die 104 may include any number of electrical contacts 106 or electrical contacts 108, respectively. The electrical contacts 106 and the electrical contacts 108 may be arranged such that each of the electrical contacts 106 couples to a respective contact of the electrical contacts 108 when the semiconductor die 102 and the semiconductor die 104 are connected. An underfill material (e.g., capillary underfill) may be provided between the semiconductor die 102 and the semiconductor die 204 to provide electrical insulation to the electrical contacts (e.g., electrical contacts 106 and electrical contacts 108).

The solder joints 110 may electrically couple the semiconductor die 102 to the semiconductor die 104 by enabling the transport of signaling through the electrical contacts 106 and the electrical contacts 108. As illustrated, solder joints 110 are present at each of the electrical contacts 106 to couple the electrical contacts 106 to the electrical contacts 108. These dies or their interconnects, however, may be designed with or develop (e.g., due to stress from heating, bonding, thinning) small inconsistencies (e.g., silicon warpage, inconsistent interconnects, and so on) such that when the dies are connected, one or more of the semiconductor dies may experience mechanical stresses that can impact the reliability of the semiconductor device (e.g., by severing a connection between the dies). The dies may be particularly affected when the dies are implemented on thin wafers, for example, in die-stacked package solution where the packages are vertically constrained. As illustrated, the semiconductor device of FIG. 1 includes the semiconductor die 102, which experiences mechanical stress that causes the die 102 to bend upward, thereby separating multiple of the electrical contacts 106 from the electrical contacts 108.

As the electrical contacts 106 are separated from the electrical contacts 108, voids 112 may be present between the electrical contacts (e.g., the electrical contacts 106 or the solder joints 110 do not directly contact the electrical contacts 108). The voids 112 can cause shorting or leakage between the electrical contacts, thereby limiting or disabling signaling between the dies (e.g., power signaling, grounding, communication signaling). As a result, the semiconductor device may experience electrical failure or fail to provide the desired functionality.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a printed circuit board (PCB) or wafer-level substrate, a die-level substrate, or another die for die-stacking or 3D1 applications. A person having ordinary skill in the relevant art will recognize that suitable steps of the methods described herein can be performed at the wafer level or at the die level. Thus, although some examples may be illustrated or described with respect to dies or wafer, the technology disclosed herein may apply to dies or wafers. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

Many embodiments of the present technology are described below in the context of manufacturing semiconductor devices, including semiconductor dies and the associated electrical connections. For example, semiconductor devices (e.g., 3D1 packaging solutions) can each include a semiconductor die with die interconnects thereon connected to an additional semiconductor die with die interconnects. The die interconnects of the multiple semiconductor dies may be coupled through solder joints. To ensure proper coupling of the multiple dies (e.g., stresses do not disrupt the connection of the dies), the semiconductor dies can each include a non-conductive bonding structure (e.g., dielectric material) that couples to a respective non-conductive bonding structure of the other semiconductor die.

As used herein, the terms “vertical,” “lateral,” “upper” and “lower” can refer to relative directions or positions of features in the semiconductor die assemblies in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down and left/right can be interchanged depending on the orientation.

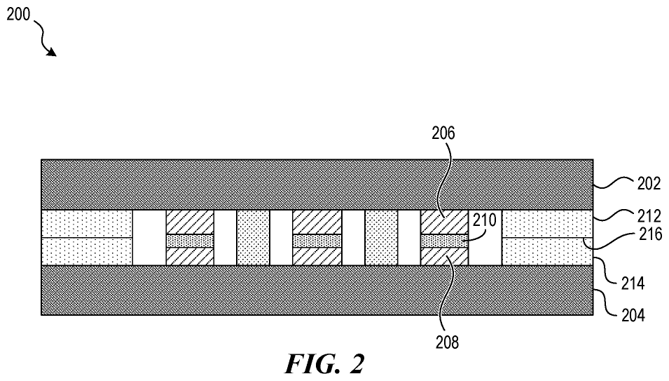

FIG. 2 illustrates a simplified schematic cross-sectional view of a semiconductor device assembly 200 in accordance with embodiments of the present technology. The semiconductor device assembly 200 includes a semiconductor die 202 mounted to an additional semiconductor die 204. Although described as an additional semiconductor die 204, it should be appreciated that the additional semiconductor die 204 may instead be implemented as a substrate to which the semiconductor die 202 attaches. For example, the substrate may connect to the semiconductor die 202 to provide external connectively to the device (e.g., power, ground, and input/output (I/O) signals) through traces, lines, vias, and other electrical connection structures in the substrate. Thus, it should be appreciated that the described techniques, apparatuses, and systems may apply not only to connections between multiple dies, but also to connections between a die and a substrate (e.g., in a flip-chip arrangement).

The die 202 can be electrically connected to the die 204 through electrical contacts 206 (e.g., interconnects). In some embodiments, the electrical contacts 206 can be structures resulting from bonding or joining (e.g., such as through solder joints, diffusion bonding, etc.) pillars, pads, or interconnect structures protruding from the die 202 to the corresponding structures (e.g., the electrical contacts 208) protruding from the die 204. As illustrated, the electrical contacts 206 are joined through solder joints 210 (e.g., solder balls, bumps, etc.). The electrical contacts 204 or the electrical contacts 208 may be include any conductive material, for example, copper (Cu), aluminum (AI), gold (Au), or any alloys thereof.

The die 202 or the die 204 may include a non-conductive bonding structure that may be used to couple the die 202 to the die 204. As illustrated, the die 202 includes the non-conductive bonding structure 212 and the die 204 includes the non-conductive bonding structure 214. The non-conductive bonding structure may protrude from the surface of the die (e.g., the inactive surface) and mate with a corresponding non-conductive bonding structure on another die. For example, non-conductive bonding structure 212 protrudes from the bottom surface of the die 202 and connects to the non-conductive bonding structure 214, which protrudes from the upper surface of the die 204. The non-conductive bonding structures may include any appropriate material that may be coupled to produce the bond 216. As a non-limiting example, the non-conductive bonding structure may include dielectric material (e.g., silicon dioxide (SiO₂), silicon nitride (SiN), silicon carbide (SiC), silicon carbon nitride (SiCN), etc.), which may be directly bonded through dielectric-dielectric (e.g., fusion) bonding.

The non-conductive bonding structure may be disposed along portions of the surface of the semiconductor die such that the non-conductive bonding structure and the electrical contacts cover all or a portion of the surface to which they protrude from. For example, the die 202 is illustrated with non-conductive bonding structure 212 and electrical contacts 206 protruding through only a portion of the bottom surface of the die. The non-conductive bonding structure or the electrical contacts may be dispersed along the surface of the die such that non-conductive bonding structure protrudes from multiple locations on the surface of the die. In aspects, dispersing the non-conductive bonding structure along the surface of the die may help ensure that the dies do not move, and the electrical contacts remain connected. Moreover, implementing the non-conductive bonding structure without covering the entire surface of the die may reduce material costs or improve heat dissipation without impacting the reliability of the semiconductor device.

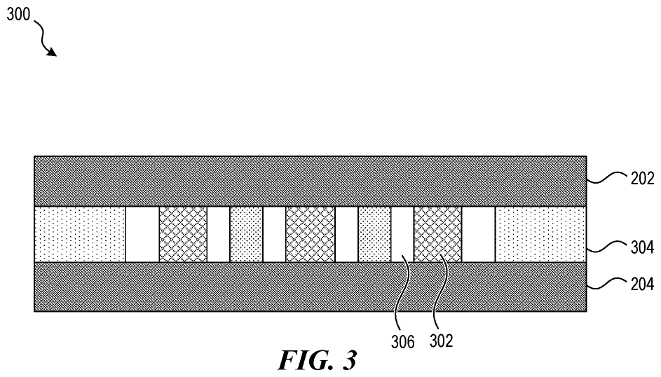

FIG. 3 illustrates a simplified schematic cross-sectional view of a semiconductor device assembly 300 in accordance with embodiments of the present technology. FIG. 3 may correspond to a cross-sectional view of the semiconductor device assembly of FIG. 2 after the electrical contacts (e.g., electrical contacts 206 and electrical contacts 208) and the non-conductive bonding structure (e.g., non-conductive bonding structure 212 and non-conductive bonding structure 214) have bonded.

In the semiconductor device assembly 300, the electrical contacts may be bonded to form bonded interconnects 302 that can couple the die 202 to the die 204 (e.g., enable power transfer, grounding, I/O communications). Although not shown, the interconnects 302 may be bonded through an intermediary metal (e.g., solder) that is located between the electrical contacts of each die. Alternatively, the interconnects 302 may exclude an intermediary metal and instead be a solid structure, for example, a solid copper structure resulting from Cu—Cu diffusion bonding.

The semiconductor device assembly 300 also includes bonded structures 304 resulting from the bond between the non-conductive bonding structure (e.g., non-conductive bonding structure 212 and non-conductive bonding structure 214). When bonded, the die 202 and the die 204 may be parallel (e.g., the mated surfaces are parallel) to maintain the balance and structural integrity of the die stack. The bonded structures 304 may physically couple the die 202 and the die 204 to ensure that stresses do not cause the dies to displace relative to one another. The bonded structures 304 may be solid structures resulting from direct bonds between the non-conductive bonding structure.

An underfill of underfill material 306 (e.g., capillary underfill) may be provided between die 202 and die 204 to provide electrical insulation to the interconnects 302. The underfill material 306 may provide thermal regulation of the semiconductor device to better dissipate heat resulting from operations of the device. Moreover, the underfill material may increase the structural integrity of the dies (e.g., die 202 and die 204) or the provide insulation to the interconnects 302.

The semiconductor device assembly 300 may include circuitry (not shown) on an active surface of the die (e.g., opposite the inactive surface from which the non-conductive bonding structure protrudes), which may provide various functionality (e.g., storage, memory, processing). For example, circuitry may be disposed on the upper surface or lower surface of the die 202 and the die 204. Although illustrated as two dies, a semiconductor device assembly may include additional dies that may be stacked on top of, placed below, or implemented adjacent to the semiconductor device assembly 300. The additional dies may be stacked in accordance with one or more of the techniques, apparatuses, or systems described herein, for example, similar to semiconductor device assembly 300.

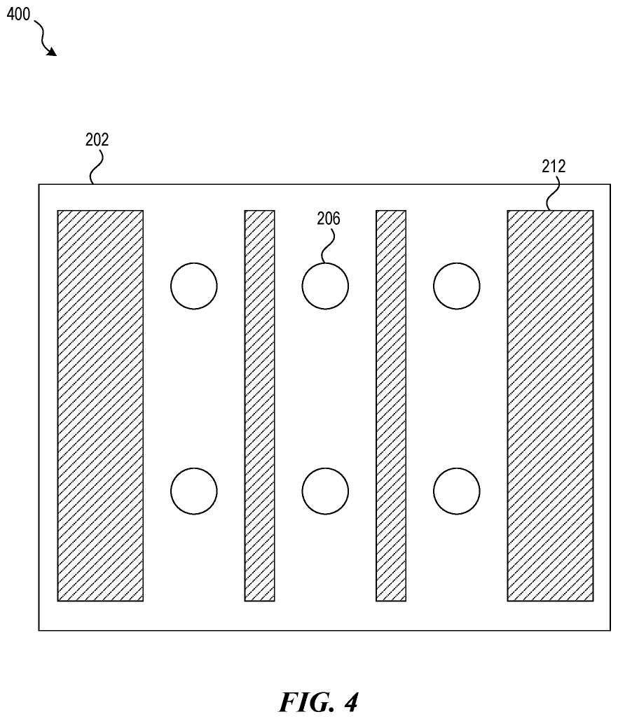

FIG. 4 illustrates a simplified schematic partial plan view of a semiconductor device assembly 400 in accordance with embodiments of the present technology. FIG. 4 may correspond to a bottom view (e.g., lower surface, inactive side) of the semiconductor die 202.

For illustrative purposes, the die 202 is shown as having a particular configuration of electrical contacts 206 and non-conductive bonding structure 212. However, it should be understood that the die 202 may have a different configuration than that shown. Moreover, although described with respect to the die 202, it should be appreciated that the techniques, apparatus, and systems for stacked semiconductors described herein may be applied to die-to-die, die-to-wafer, or wafer-to-wafer bonding. Thus, in some implementations the die 202 of FIG. 4 may instead be replaced with a wafer containing multiple dies.

The die 202 is illustrated with six electrical contacts 206 and four sections of non-conductive bonding structure 212. The electrical contacts 206 may be distributed throughout the die 202 to enable various circuitry disposed on the active side of the die 202 to couple to the electrical contacts 206. The size or shape of any of the electrical contacts 206 may be the same as or different from the size of any other of electrical contacts 206. The electrical contacts 206 may be composed of a same material or multiple different materials.

The die 202 is also illustrated to include the non-conductive bonding structure 212. The non-conductive bonding structure 212 is distributed into multiple sections of material protruding from the surface of the die 202. In some implementations, the non-conductive bonding structure 212 may be implemented as a single continuous structure (e.g., in contrast to the discrete and disconnected structures shown). The non-conductive bonding structure 212 may have a uniform height to enable an additional die (e.g., die 204 of FIG. 2) to evenly couple to the die 202. Some designs may only require a small bonding surface to couple the multiple dies. Thus, the non-conductive bonding structure 212 may not be required to cover the entire surface of the die 202. For example, the non-conductive bonding structure 212 and the electrical contacts 206 only cover a portion of the inactive surface of the die 202 (e.g., the area of the electrical contacts 206 and the non-conductive bonding structure 212 along a plane parallel to the surface of the die 202 (the plane shown in FIG. 4) is less than an area of the surface of the die 202).

By providing the non-conductive bonding structure 212 on the surface of the die 202 (e.g., the mating surface), the die 202 may bond to a corresponding non-conductive bonding structure on an additional die. In doing so, the non-conductive bonding structure 212 may guarantee a minimum spacing between the dies (e.g., based on the height of the non-conductive bonding structure 212) and ensure that stresses resulting from connecting the dies do not damage the connection between the dies. Thus, the non-conductive bonding structure 212 may improve the mechanical robustness or the thermal regulation of the device.

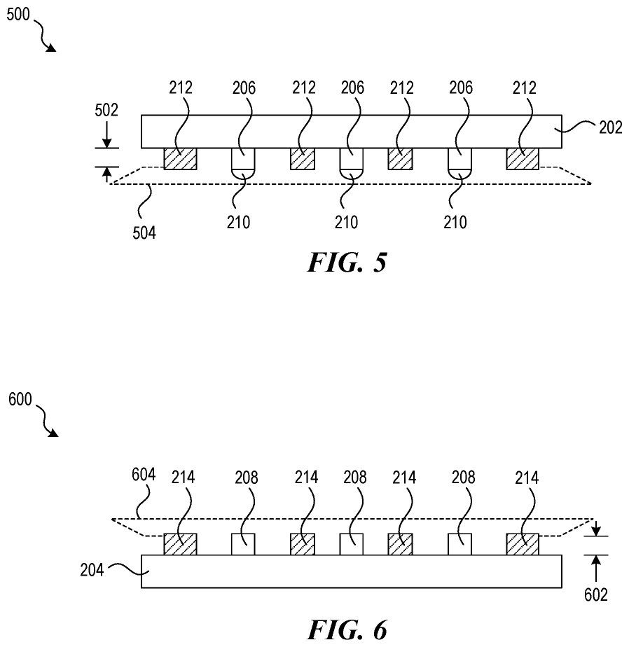

FIGS. 5 through 7 illustrate simplified schematic cross-sectional views of a semiconductor device assembly at selected stages in a manufacturing method in accordance with an embodiment of the present technology. As illustrated in FIG. 5, the method can include a stage for providing the die 202. The die 202 can include die electrical contacts 206 (e.g., solid metal structures or interconnects for providing electrical connections to circuits within the die 202) protruding below a die bottom surface (e.g., the surface shown in FIG. 4). The die 202 can further include a non-conductive bonding structure 212 (e.g., a dielectric material that may be bonded to a similar material on an additional die). The non-conductive bonding structure 212 may protrude from the die bottom surface at any location, including multiple locations.

The die 202 with the electrical contacts 206 and the non-conductive bonding structure 212 can be manufactured using a separate manufacturing process (e.g., wafer or die-level manufacturing process). The separate manufacturing process can produce the electrical contacts 206 and the non-conductive bonding structure 212 according to a protrusion measure 502 (e.g., a height of the structures, such as a length measured between the die bottom surface and a distal portion of the electrical contacts 206 and the non-conductive bonding structure 212). In some embodiments, the protrusion measure 502 can include a distance less than 20 μm. According to the protrusion measure 502, the distal portions (e.g., relative to the die bottom surface) of the electrical contacts 206 and the non-conductive bonding structure 212 can be coplanar along a horizontal plane 504 that is parallel with the die bottom surface.

Solder joints 210 may be provided at the distal end of the electrical contacts 206 to bond the electrical contacts 206 to corresponding contacts on an additional die. In some implementations, the solder joints 210 and the electrical contacts 206 may be manufactured such that a height of the solder joints 210 and the electrical contacts 206 is equal to the protrusion measure 502 (e.g., a same height as the non-conductive bonding structure 212). Alternatively, the electrical contacts 206 may not be bonded through an intermediary metal (e.g., solder), but instead through direct bonding (e.g., hybrid bonding or fusion bonding).

As illustrated in FIG. 6, the method can include a stage for providing an additional die 204. Although illustrated and described as a die, the die 204 may alternatively be a substrate to which the die 202 is bonded. The die 204 can include electrical contacts 208 (e.g., solid metal structures or interconnects for providing electrical connections to the die 204) protruding above a die top surface (e.g., the top surface of the die 204 based on the orientation in FIG. 2). The die 204 can further include a non-conductive bonding structure 214 (e.g., a dielectric material, such as silicon dioxide or silicon nitrogen, that may be bonded to a similar material on an additional die). The non-conductive bonding structure 214 may protrude from the die top surface at any location, including locations that correspond to the locations of the non-conductive bonding structure 212 on the die 202 of FIG. 5.

Similar to the die 202 of FIG. 5, the die 204 with the electrical contacts 208 and the non-conductive bonding structure 214 can be manufactured using a separate manufacturing process (e.g., wafer or die-level manufacturing process). Like the stage illustrated in FIG. 5, the separate manufacturing process can produce the electrical contacts 206 and the non-conductive bonding structure 214 according to a protrusion measure 602 (e.g., a height of the metal structures, such as a length measured between the die top surface and a distal portion of the electrical contacts 208 and the non-conductive bonding structure 214). The protrusion measure 602 may be the same as or different from the protrusion measure 502 of FIG. 5. In some embodiments, the protrusion measure 602 can include a distance less than 20 μm. According to the protrusion measure 602, the distal portions (e.g., relative to the die top surface) of the electrical contacts 208 and the non-conductive bonding structure 214 can be coplanar along a horizontal plane 604 that is parallel with the substrate top surface.

As illustrated in FIG. 7, the method can include a stage for aligning and bonding the die 202 and the die 204 to create the semiconductor device assembly 700. The die 202 and the die 204 can be aligned based on aligning reference portions (e.g., a center portion, a periphery edge or surface, etc.) thereof along a line or a plane. The structures can be aligned such that the electrical contacts 206 and the electrical contacts 208 or the non-conductive bonding structure 212 and the non-conductive bonding structure 214 are aligned along a line or a plane (e.g., a vertical line or plane). Further, the structures can be aligned such that the non-conductive bonding structure 212 and the non-conductive bonding structure 214 directly contact each other. The electrical contacts 206 and the electrical contacts 208 may be similarly aligned.

Once aligned, the method can include a stage for bonding the metal structures (e.g., the electrical contacts 206 to the electrical contacts 208 or the non-conductive bonding structure 212 to the non-conductive bonding structure 214). For example, the electrical contacts may be bonded through an intermediary metal, as illustrated, solder joints 210 (e.g., a solder cap). Alternatively, the electrical contacts may be bonded through a diffusion bonding process (e.g., Cu—Cu diffusion bonding) that includes a solid-state welding process for joining metals based on solid-state diffusion. The bonding process can include creating a vacuum condition or exposing the structures to an inert gas, heating the structures, pressing the structures together, or a combination thereof. The non-conductive bonding structures (e.g., non-conductive bonding structure 212 and non-conductive bonding structure 214) may also be bonded once aligned. The non-conductive bonding structures may be coupled through any direct bonding technique to create the bond 216. As non-limiting examples, the bond 216 may include a dielectric bond (e.g., silicon dioxide bond or a silicon nitrogen bond). The bonding process for creating the bond 216 may include any number of operations, including those described for bonding the electrical contacts.

Based on the bonding stage, the structures can bond or fuse and form a continuous structure. For example, non-conductive bonding structure 212 and the non-conductive bonding structure 214 can be bonded to form the bonded structures 304 of FIG. 3. Also, for example, the electrical contacts 206 and the electrical contacts 208 can be bonded to form the interconnects 302 of FIG. 3. In some implementations, the interconnects 302 may include an intermediary metal, for example, the solder joints 210. The non-conductive bonding structure and the electrical contacts may be bonded in a single bonding process or through different processes.

The bonding stage may additionally include providing a underfill material 306 between the die 202 and the die 204. The underfill material 306 may be disposed in any location between the die 202 and the die 204 that is not filled by the interconnects 302 or the bonded structures 304. By providing the underfill material 306 between the dies, the interconnects 302 may be electrically insulated, the device may be thermally regulated, or the dies may be structurally supported.

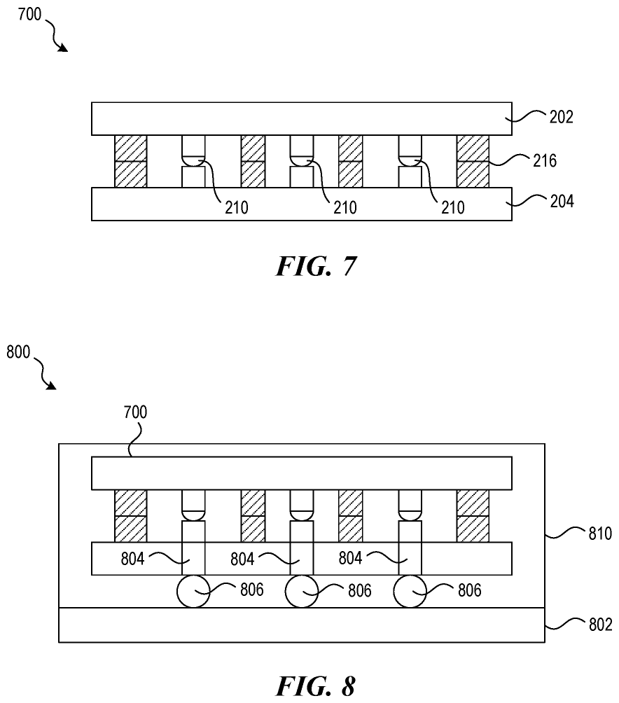

FIG. 8 illustrates a simplified schematic cross-sectional view of a semiconductor device assembly 800 in accordance with an embodiment of the present technology. The semiconductor device assembly illustrated in FIG. 8 may correspond to the semiconductor device assembly 700 of FIG. 7 assembled onto a substrate 802 and packaged. The semiconductor device assembly 700 may include a through-silicon via (TSV) die assembly, including a 3D1 device or a die-stacked package. The semiconductor device assembly 800 may include multiple stacked dies (e.g., die 202 and die 204 of FIG. 2 or any other additional die). The multiple stacked dies may be assembled onto the substrate 802 and packaged as any appropriate semiconductor device (e.g., a memory chip, processor, microprocessor, system-on-chip, and so on). Although not shown, the substrate 802 may include non-conductive bonding structures that protrude from the surface of the substrate and couple to non-conductive bonding structures on one or more die of the semiconductor device assembly 800.

Metal or conductive interconnects (e.g., electrical contacts 206 or electrical contacts 208) can extend vertically to directly contact and electrically (e.g., communicatively) couple the dies. Electrical connections 806 may extend from the substrate 802 and directly contact the bottom die or an interconnect of the bottom die. The electrical connections 806 may include contact pads on the lower surface of the bottom die, solder balls, or contact pads on the substrate 802. In general, however, the semiconductor device assembly 700 may couple to the substrate 802 and any external connections thereof to provide functionality to a device in which it is implemented.

In some embodiments, the dies (or the die and the substrate) can electrically connect to each other directly without routing through electrical circuits in an intervening die located between the coupled dies. For example, one or more of the dies can include one or more TSVs 804 (e.g., vertical interconnects that pass completely through the die thereon). Based on the TSVs 804, the upper die can electrically connect to the substrate 802 or another die directly (e.g., without electrically routing through circuits in the lower die) while passing the electrical signals or levels through the middle die. The TSVs 804 can directly contact the interconnects (e.g., the electrical contacts 206, the electrical contacts 208, or the electrical contacts 806), to electrically couple the TSVs 804 and the interconnects.

Although illustrated as a two-die semiconductor device assembly, a device assembly may include a greater number of dies than illustrated. For example, one or more additional die may be stacked on top of, placed below, or assembled adjacent to the two dies shown. Each of the additional dies may be coupled to one another or the illustrated dies through a coupling, including electrical contacts and non-conductive bonding structures. The dies may be stacked in accordance with the method described with respect to FIGS. 5 through 7. One or more of the illustrated dies or the additional dies may include at least one TSV to couple the multiple dies within the stacked die assembly.

The substrate-mounted semiconductor device assembly may then be packaged as any suitable semiconductor device for integration within an electronic device. The semiconductor device assembly may be packaged by providing an encapsulant 810 (e.g., mold material) that encapsulates the multiple semiconductor dies (e.g., die 202 and die 204). The encapsulant 810 may act as a protecting covering for the dies to prevent damage from contact, radiation, and so on. The encapsulant 810 may enclose one or more sets of semiconductor dies assembled in multiple semiconductor device assemblies or a single semiconductor device assembly. The size of the packaged semiconductor device may vary based on the number or size of dies implemented within the device. Generally, however, a semiconductor device assembly configured through one or more aspects of the present technology may provide an efficient and robust solution to packaging multiple memory dies (e.g., as a stacked-die assembly or 3D1 package).

In accordance with one aspect of the present disclosure, the semiconductor devices illustrated in the assemblies of FIGS. 2-8 could be memory dies, such as dynamic random-access memory (DRAM) dies, NOT-AND (NAND) memory dies, NOT-OR (NOR) memory dies, magnetic random-access memory (MRAM) dies, phase change memory (PCM) dies, ferroelectric random-access memory (FeRAM) dies, static random-access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

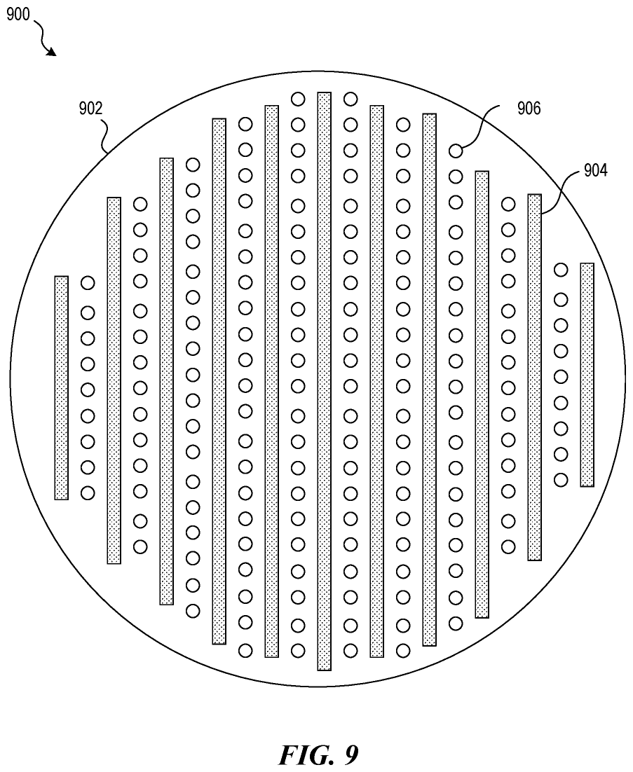

Although in the foregoing example embodiments, assemblies have been illustrated and described as formed at the die-level, in other embodiments of the present disclosure wafer-level bonding processes can enjoy the benefits of the improved bonding techniques described above. In this regard, FIG. 9 illustrates a simplified schematic plan view of a wafer 902 that may be implemented to fabricate a plurality of semiconductor device assemblies in accordance with an embodiment of the present technology. The plan view of the wafer 902 may correspond to either a front side (e.g., active side) of the wafer 902 on which circuitry is formed, or a back side (e.g., inactive side) of the wafer 902 opposite the front side. Non-conductive bonding structures 904 (e.g., non-conductive bonding structure 212 or non-conductive bonding structure 214 of FIG. 2) may be deposited on the inactive side of the wafer 902 to provide adequate bonding to another die or wafer in a manner analogous to the die-die bonding described and illustrated above.

Interconnects 906 (e.g., contact pads, conductive structures, etc.) may be disposed at the surface of the wafer 902 to enable the wafer to be coupled to various electrical connections. The interconnects 906 may be deposited in locations that do not include the non-conductive bonding structures 904. The non-conductive bonding structures 904 and the interconnects 906 may be disposed at the wafer 902 such that each semiconductor die fabricated from the wafer contains a corresponding array of interconnects 906, to enable electrical connectivity to the die.

The non-conductive bonding structure 904 may be deposited such that it matches a non-conductive bonding structure present on another wafer or die. For example, the non-conductive bonding structure 904 may have a particular shape or pattern such that, when it is coupled to an additional wafer or die, a non-conductive bonding structure present on that wafer or die corresponds to the non-conductive bonding structure 904. The wafer 902 may be bonded using wafer-level bonding or die-level bonding, including die-to-wafer bonding. Thus, for die-level bonding, the non-conductive bonding structure 904 may be designed such that each die includes at least a portion of the non-conductive bonding structure 904.

The non-conductive bonding structure 904 may be deposited at any step in the manufacturing process of the semiconductor device. For example, the non-conductive bonding structure 904 may be deposited after a wafer thinning (e.g., back grinding process) of the wafer 902. The configuration of the non-conductive bonding structure 904 may vary across different wafers based on the characteristics of the wafer or the circuitry deposited thereon. For example, thinner wafers may require larger surface areas of non-conductive bonding structures to resist stresses that may result from die bonding (e.g., due to heating, design inconsistencies, and so on). Some wafers may include non-conductive bonding structures 904 at locations where the wafer is most likely to warp (e.g., the periphery of the wafer) to prevent warpage from occurring. In general, the non-conductive bonding structure 904 may be designed to cover only a portion of the surface of the wafer 902 (e.g., in contrast to the entire surface). In doing so, the wafer 902 may be used to fabricate a semiconductor device with lower cost, improved thermal regulation, and reduced fabrication time.

It should be noted that the configuration shown is but one example of an example substrate that may be used to fabricate a semiconductor device assembly and other configurations are possible. For example, the non-conductive bonding material 904 and the interconnects 906 could be implemented at different locations at the wafer 902. Given that the bonding may occur at the die level, the wafer 902 may instead be replaced with a die-level substrate (e.g., a substrate capable to support a single die, such as die 202 or die 204). A non-conductive bonding structure 904 may be deposited at the die level before or after dicing of the wafer has occurred. It should also be appreciated that, although shown with a particular shape, the wafer 902 may have any other shape, size, or configuration.

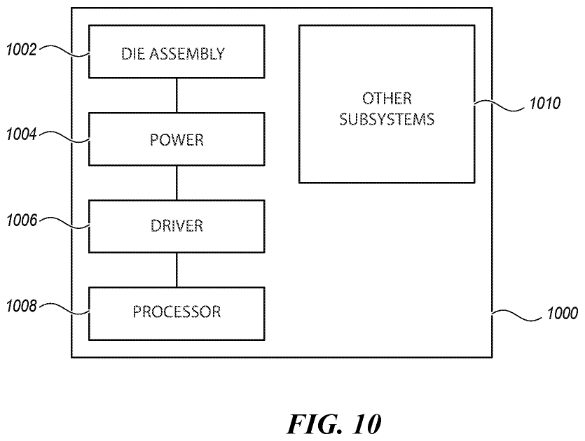

Any one of the semiconductor devices and semiconductor device assemblies described above with reference to FIGS. 2-9 can be incorporated into any of a myriad of larger and/or more complex systems, a representative example of which is system 1000 shown schematically in FIG. 10. The system 1000 can include a semiconductor device assembly 1002 (e.g., or a discrete semiconductor device), a power source 1004, a driver 1006, a processor 1008, and/or other subsystems or components 1010. The semiconductor device assembly 1002 can include features generally similar to those of the semiconductor devices described above with reference to FIGS. 2-9. The resulting system 1000 can perform any of a wide variety of functions, such as memory storage, data processing, and/or other suitable functions. Accordingly, representative systems 1000 can include, without limitation, hand-held devices (e.g., mobile phones, tablets, digital readers, and digital audio players), computers, vehicles, appliances and other products. Components of the system 1000 may be housed in a single unit or distributed over multiple, interconnected units (e.g., through a communications network). The components of the system 1000 can also include remote devices and any of a wide variety of computer readable media.

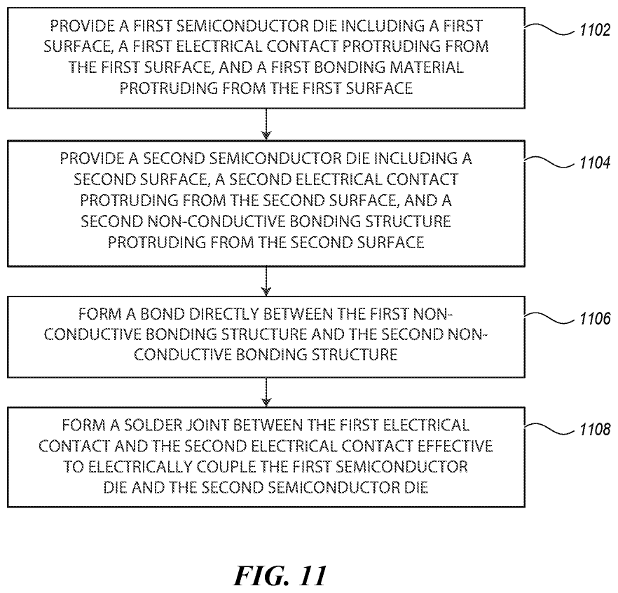

FIG. 11 illustrates an example method for fabricating a semiconductor device assembly in accordance with an embodiment of the present technology. The method may, for illustrative purposes, be described with respect to features, components, or elements of FIGS. 2-10. Although illustrated in a particular configuration, one or more operations of the method may be omitted, repeated, or reordered. Additionally, the method may include other operations not illustrated in FIG. 11.

At 1102, a first semiconductor die 202 is provided. The first semiconductor die 202 may include a first surface, a first electrical contact 206 protruding from the first surface, and a first non-conductive bonding structure 212 protruding from the first surface. The electrical contact 206 may be composed of a conductive material that may electrically couple the die 202 to another die or substrate. The non-conductive bonding structure 212 may include a dielectric material that can bond to another like material on an addition die or substrate. The first semiconductor die 202 may include an active surface opposite the first surface on which circuitry is disposed.

At 1104, a second semiconductor die 204 is provided. The second semiconductor die 204 may include a second surface, a second electrical contact 208 protruding from the second surface, and a second non-conductive bonding structure 214 protruding from the second surface. The electrical contacts 208 may be similar to the electrical contacts 206 of the die 202. The non-conductive bonding structure 214 may be designed or composed of material similar to the non-conductive bonding structure 212. In some implementations, the second semiconductor die 204 may be replaced with a substrate, to perform a bond between the die 202 and a substrate. Alternatively, the die 204 may include a surface opposite the second surface that couples to a substrate 802.

At 1106, a bond may be formed between the first non-conductive bonding structure 212 and the second non-conductive bonding structure 214. The bond may include a dielectric bond formed through directly bonding the first non-conductive bonding structure 212 to the second non-conductive bonding structure 214. As such, the bond 216 may not include an intermediary metal, and the first non-conductive bonding structure 212 and the second non-conductive bonding structure 214 may fuse to become a single bonded structure 302. In some implementations, multiple portions of the non-conductive bonding structure 212 and the non-conductive bonding structure 214 may be bonded, for example, when the non-conductive bonding structures are dispersed throughout the dies.

At 1108, a solder joint is formed between the first electrical contact 206 and the second electrical contact 208 to electrically couple the first semiconductor die 202 and the second semiconductor die 204 to create the interconnect 302. The method 1100 may further include providing a underfill material 306 between the first semiconductor die 202 and the second semiconductor die 204. Once coupled, the first semiconductor die 202 and the second semiconductor die 204 may operate alone or in combination with other semiconductor dies to provide functionality to a device in which it is implemented. In this way, performing the method may fabricate a reliable, cost-effective semiconductor device.

Although described with respect to certain elements and features, functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

It should be noted that the methods detailed above describe possible implementations, and that the operations and the steps may be rearranged or otherwise modified such that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a first semiconductor die having a first surface;
a first non-conductive bonding structure protruding from the first surface;
a first electrical contact coupled to the first semiconductor die and protruding from the first surface;
a second semiconductor die having a second surface;
a second non-conductive bonding structure protruding from the second surface;
a second electrical contact coupled to the second semiconductor die and protruding from the second surface; and
a solder joint coupling the first electric contact to the second electric contact,
wherein the first non-conductive bonding structure is directly bonded to the second non-conductive bonding structure by a dielectric-dielectric bond.

2. The semiconductor device assembly of claim 1, further comprising a substrate, wherein a third surface of the first semiconductor die couples to the substrate, the third surface different than the first surface.

3. The semiconductor device assembly of claim 1, further comprising an underfill material disposed between the first semiconductor die and the second semiconductor die.

4. The semiconductor device assembly of claim 1, wherein the first electrical contact couples to a through-silicon via of the first semiconductor die.

5. The semiconductor device assembly of claim 1, wherein the first non-conductive bonding structure and the second non-conductive bonding structure each comprises silicon oxide, silicon nitride, silicon carbide, silicon carbon nitride, or a combination thereof.

6. The semiconductor device assembly of claim 5, wherein the first non-conductive bonding structure comprises a different material than the second non-conductive bonding structure.

7. The semiconductor device assembly of claim 1, further comprising an encapsulant that at least partially encapsulates the first semiconductor die and the second semiconductor die.

8. The semiconductor device assembly of claim 1, wherein:
a first cross section of the first non-conductive bonding structure and the first electrical contact along a first plane parallel to the first surface has a first area that is smaller than a second area of the first surface; or
a second cross section of the second non-conductive bonding structure and the second electrical contact along a second plane parallel to the second surface has a third area that is smaller than a fourth area of the second surface.

9. The semiconductor device assembly of claim 1, further comprising:
a third surface of the first semiconductor die opposite the first surface, wherein first circuitry is disposed at the third surface; or
second circuitry disposed at the second surface.

10. The semiconductor device assembly of claim 1, wherein the first electrical contact and the second electrical contact are configured to communicatively couple the first semiconductor die and the second semiconductor die.

11. A method of making a semiconductor device assembly, comprising:
providing a first semiconductor die including a first surface, a first electrical contact protruding from the first surface, and a first non-conductive bonding structure protruding from the first surface;
providing a second semiconductor die including a second surface, a second electrical contact protruding from the second surface, and a second non-conductive bonding structure protruding from the second surface;
forming a dielectric-dielectric bond directly between the first non-conductive bonding structure and the second non-conductive bonding structure; and
forming a solder joint between the first electrical contact and the second electrical contact effective to electrically couple the first semiconductor die and the second semiconductor die.

12. The method of claim 11, further comprising disposing an underfill material between the first semiconductor die and the second semiconductor die.

13. The method of claim 11, further comprising providing a substrate coupled to a third surface of the first semiconductor die, the third surface opposite the first surface.

14. The method of claim 11, further comprising:
providing an encapsulant that at least partially encapsulated the first semiconductor die and the second semiconductor die.

15. The method of claim 11, further comprising:
providing a through silicon via at the first semiconductor die at that extends through the first semiconductor die and couples to the first electrical contact.

16. A semiconductor device assembly, comprising:
a stack of multiple semiconductor dies, each semiconductor die of the multiple semiconductor dies coupled to another semiconductor die of the multiple semiconductor dies through one or more respective couplings; and
the one or more respective couplings, each of the one or more respective couplings comprising:
a first respective non-conductive bonding structure protruding from a first respective semiconductor die;
a first respective electrical contact protruding from the first respective semiconductor die;
a second respective non-conductive bonding structure protruding from a second respective semiconductor die;
a second respective electrical contact protruding from the second respective semiconductor die; and
a respective soldering joint coupling the first respective electrical contact and the second respective electrical contact,
wherein the first respective non-conductive bonding structure is directly coupled to the second respective non-conductive bonding structure through a dielectric bond.

17. The semiconductor device assembly of claim 16, wherein the first respective bonding structure and the second respective bonding structure each comprises silicon oxide, silicon nitride, silicon carbide, silicon carbon nitride, or a combination thereof

18. The semiconductor device assembly of claim 16, further comprising a substrate coupled to the stack of multiple semiconductor dies.

19. The semiconductor device assembly of claim 16, further comprising an encapsulant that at least partially encapsulates the stack of multiple semiconductor dies.

20. The semiconductor device assembly of claim 16, wherein each of the one or more respective couplings further comprises an underfill material disposed between the first respective semiconductor die and the second respective semiconductor die.
